(19) United States
(12) Patent Application Publication
(10) Pub. No.: US 2014/0373890 A1
(43) Pub. Date: Dec. 25, 2014

(54) NANOCOMPOSITE THERMOELECTRIC DEVICES

(71) Applicant: Empire Technology Development LLC, Wilmington, DE (US)

(72) Inventor: Arockiadoss THEVASAHAYAM, Tamailnadu (IN)

(21) Appl. No.: 14/313,346

(22) Filed: Jun. 24, 2014

(30) Foreign Application Priority Data
Jun. 24, 2013 (IN) 2715/CHE/2013

(51) Int. Cl. H01L 37/00; H01F 1/01; B29C 39/00; H01F 1/42

(52) U.S. Cl. CPC H01L 37/00; H01F 1/42; H01F 1/01; B29C 39/003; B29K 2505/12
USPC 136/203; 252/62.51 R; 264/427

(57) ABSTRACT

Thermoelectric cooling devices and methods for producing and using the devices are disclosed, wherein the cooling devices include a polymer composite of a polymer and nanoparticles of at least one paramagnetic material. A source for producing an electric field within the polymer composite produces a corresponding heat transfer from one surface of the composite to the other.

### CLAIM OF PRIORITY

This application claims priority benefit under Title 35§119(a) of Indian Patent Application No. 2715/CHE/2013, filed Jun. 24, 2013, entitled “Nanocomposite Thermoelectric Devices,” the disclosure of which is incorporated by reference in its entirety.

### BACKGROUND

Refrigeration has many applications, including, but not limited to household refrigerators, industrial freezers, cryogenics, and air conditioning. For refrigeration, heat is removed from a low-temperature space or source and rejected to a high-temperature sink with the help of external work. The work of heat transport in refrigeration units is commonly driven by mechanical work, but can also be driven by heat, magnetism, electricity, laser, or by other means.

Vapor-compression cycling is used in most refrigeration systems. In this type of systems, a circulating refrigerant, such as Freon, is compressed and condensed, and then expanded to cool the refrigerant. The cold liquid-vapor mixture travels through an evaporator coil or tubes and is completely vaporized by passing the air to be cooled across the evaporator. cooling the warm air (from the space being refrigerated) being blown by a fan across the evaporator coil or tubes.

Vapor-compression systems are, however, energy intensive and may use ozone destroying chemicals, such as chlorofluorocarbons, hydrochlorofluorocarbons, or propane. These materials have fallen out of favor recently. Alternative systems may use carbon dioxide as the refrigerant. However, carbon dioxide systems require special design as very high pressures are encountered, and this adds to the weight and the cost of the system.

Other alternate technologies, such as thermoelectrics are expensive. Magnetic and acoustic based cooling technologies still require significant development. Thermoelectrics based on the Peltier effect, is the direct conversion of temperature differences into electricity, and the conversion of electricity into temperature differences. However, despite decades of research into thermoelectric materials and appliances, the efficiency of thermoelectric devices has remained low. Thus, there remains a need for more efficient thermoelectric devices.

### SUMMARY

Efficient thermoelectric devices may be produced from polymer/nanoparticle composites that exhibit spin transport electronics, or spintronics. Spintronics takes into account both the intrinsic spin of the electron and its associated magnetic moment, in addition to its fundamental electronic charge, thereby providing a spin-induced Peltier effect.

In an embodiment, a cooling device includes a polymer composite that includes at least one polymer and nanoparticles that include at least one paramagnetic material.

In an embodiment, a method for producing a cooling device includes forming a polymer composite by dispersing nanoparticles of at least one paramagnetic material in a polymer.

In an embodiment, a thermal transfer system configured to heat or cool a material includes a thermal transfer device. The thermal transfer device includes a polymer composite that includes a polymer and nanoparticles of at least one paramagnetic material. The thermal transfer device also includes a pair of electrodes coupled to the polymer composite, wherein the pair of electrodes are configured to produce an electric field within the polymer composite when active. The thermal transfer device has a first side that heats responsive to the electric field, and a second side that cools responsive to the electric field. The material may be thermally coupled to either the first side or the second side of the thermal transfer device.

### BRIEF DESCRIPTION OF THE FIGURES

FIG. 1 depicts a schematic representation of a thermoelectric cooling device according to an embodiment.

FIG. 2 depicts a configuration for using the thermoelectric cooling device of FIG. 1 according to an embodiment.

FIG. 3 depicts an alternative configuration of a thermoelectric cooling device and use thereof according to an embodiment.

FIG. 4 depicts an additional configuration of a thermoelectric cooling device and use thereof according to an embodiment.

### DETAILED DESCRIPTION

When electric current is passed through a circuit of material that has two dissimilar conductors, the thermoelectric ‘Peltier effect’ occurs at the junctions of the conductors and one of the junctions becomes hot and the other junction becomes cold. It has been determined that this effect may be enhanced by the inclusion of a material that is able to provide spin transport electronics to the material.

The enhanced thermoelectric differential observed with spin caloritronics material may be attributed to the combination of conventional thermoelectrics (which does not consider spin transport) and conventional spintronics (which does not consider heat transport). In other words, the transport of heat is intertwined with the transport of spin (that is, the intrinsic angular momentum of electrons). Additional discussion of this behavior is provided further below.

A thermoelectric material that exhibits spin transport electronics may be a polymer composite that includes nanoparticles having at least one paramagnetic material and a polymer. When placed in an electric field to induce an electric field within the material, a temperature differential may be produced across the material.

In an embodiment, the paramagnetic material may have at least one unpaired electron. However, with a greater number of unpaired electrons, the effect may be enhanced. In this regard, the paramagnetic material may have one unpaired electron, two unpaired electrons, three unpaired electrons, four unpaired electrons, or five or more unpaired electrons.

Magnetic fields are generated by moving electric charges. Electrons have an intrinsic spin, and because electrons have a charge, this rotational motion generates a magnetic field that points in a particular direction. When electrons are paired in an orbital, they have opposite spins, causing their magnetic fields to point in opposite directions and cancel out. In paramagnetic materials, there are unpaired electrons that do not have a partner to cancel out their magnetic fields. Thus, for paramagnetic materials having unpaired electrons in any orbital (atomic or molecular, bonding or antibonding), there will be a net magnetic field that will tend to align with an external magnetic field, and the greater the number of unpaired electrons, the stronger this effect may be. The number of unpaired electrons therefore relates to the effective magnetic moment (magnitude of the paramagnetism) of a magnet, with materials having more unpaired electrons having larger magnetic moments.

In an embodiment, a thermoelectric material that exhibits spin transport electronics may be a polymer composite of at least one polymer and nanoparticles of at least one paramagnetic material having a magnetic moment greater than or equal to about 5. In an alternative embodiment, the paramagnetic material may have a magnetic moment of at least about 4, but materials with higher magnetic moment may provide for increased efficiency, with a proposed relationship of increasing efficiency occurring with increasing magnetic moment.

In an embodiment, the polymer composite may include a polymer and nanoparticles of at least one paramagnetic material in approximately the following corresponding relative proportions (by weight), 2:1 to 4:1. Material components may be varied accordingly to provide a stable, flexible, composite material. Some examples of paramagnetic materials may include metal complexes of the transition metals. In various embodiments, while not being limited to the following, the paramagnetic material may be selected from the group consisting of FeCl₃.6H₂O, NH₄[Fe(SO₄)₂].12H₂O, (NH₄)₂[Mn(SO₄)₂].6H₂O, [Mn(NH₃)₆]Cl₂, NiCl₂.6H₂O, CoCl₂.6H₂O, and combinations thereof.

The paramagnetic material particles have a cross-sectional dimension, and the cross-sectional dimension of the particles may be about 200 nanometers or smaller. Smaller particle sizes may provide for increased efficiency as more particle sites may exist in the polymer structure. In an embodiment, the particles may have an average size of about 30 nm to about 50 nm. Some examples of the size of the particles may be, for example, less than about 200 nm, less than about 175 nm, less than about 150 nm, less than about 125 nm, less than about 100 nm, less than about 75 nm, less than about 50 nm, or any sizes between any of the listed values or smaller than the listed values.

In an embodiment, nanoparticles may be prepared by dispersing the nanoparticles in an alcohol solution and sonicating the alcohol solution for a period of time sufficient for reducing the cross-sectional size of the nanoparticles to the size desired. Alternate nanomization methods for reducing the particles size, or producing particles of the appropriate size may also be employed.

The polymer of the composite may include at least one of gelatin, polyvinyl alcohol, salts of alginic acid, polypyrrole, polymethyl methacrylate, and polyurethane. In an embodiment, the polymer composition may include polyvinyl alcohol, gelatin, and salts of alginic acid in approximately the following corresponding relative proportions (by weight), 3.5-6.2:0.8-1.2:0.8-1.2. Material components may be varied accordingly to provide a stable, flexible, composite material.

In one embodiment, the polymer composite may include polyvinyl alcohol, gelatin, an alginate, and nanoparticles of a paramagnetic material in approximately the following corresponding relative proportions (by weight) 4.5-5.5:0.9-1.1:0.9-1.1:2.2-2.5. In various embodiments, the alginate may be one of sodium alginate, potassium alginate, or combinations thereof. Upon drying, the final polymer composite may have a residual water content that is based on the water holding capacity of the polymers. As an example, the water content may be about twice the amount of the polymer.

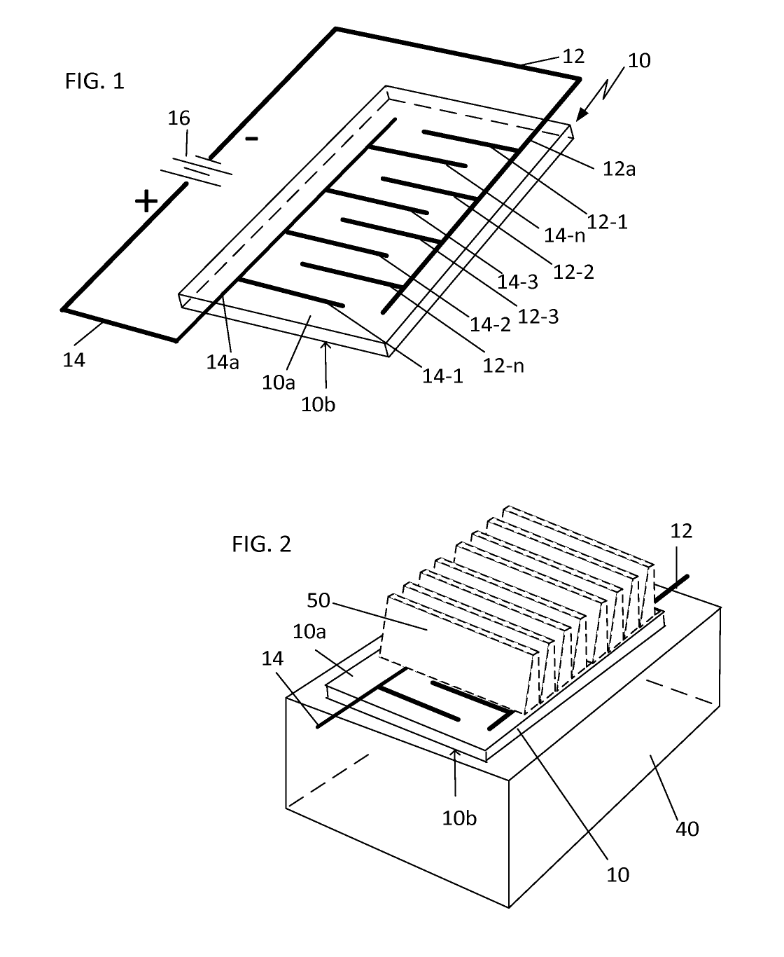

The thermoelectric effect may be produced with the polymer/paramagnetic material composite by applying an electric field to the composite. In an embodiment, an electric field may be generated by an external source, and the composite may be placed into the electric field. The external source may be two oppositely charged and spaced apart electrodes. Alternatively, as shown in FIG. 1, electrodes 12, 14 may be embedded within the polymer composite 10 to induce an electric field in the polymer. A plurality of oppositely charged electrodes 12, 14 may be alternately interspersed within the composite at a distance that is less than or equal to about 3 cm. In an embodiment, the distance between electrodes may be about 0.5 cm or less. In various embodiments, the distance between the electrodes may be configured to provide the greatest temperature decrease at the cooling surface for the configuration of materials being used. As examples, the distance between the electrodes may be approximately any of 3 cm, 2.5 cm, 2 cm, 1.5 cm, 1 cm, 0.5 cm, 0.4 cm, 0.3 cm, or any value between any of the listed values.

Alternatively, as shown in FIG. 1, the electrodes 12, 14 may have a comb-shaped configuration with each electrode having a main feed line 12a, 14a with a plurality of spaced apart branches 12-1 to 12-n, 14-1 to 14-n extending from the main feed line. As an example, the branches 12-1 to 12-n may be spaced at most about 1 cm apart along the main feed line 12a, and the branches 14-1 to 14-n may be spaced at most about 1 cm apart along the main feed line 14a. The branches 12-1 to 12-n may be interleaved between branches 14-1 to 14-n of the opposite charge so that the spacing between oppositely charged branches may be at most about 0.5 cm. As mentioned above, the distance between the electrode branches may be configured to provide the greatest temperature decrease at the cooling surface for the configuration of materials being used. The distance between interspersed branches may be any of the distances as previously discussed.

The electrodes 12, 14 may be connected to a DC power supply 16 and a voltage with current injection may be applied to the electrodes, thereby resulting in heating at one of the surfaces, that may be surface 10a of the composite 10, and cooling at the opposite surface, or surface 10b. The electric power supplied (current/voltage) may be configured to provide the greatest decrease in temperature at the cooling surface for the configuration of materials and electrodes being used. As examples, while not limited to the following, some examples of the applied DC voltage may be about 0.5 volts, about 1 volt, about 2 volts, about 3 volts, about 4 volts, about 5 volts, about 6 volts, about 7 volts, about 8 volts, about 9 volts, about 10 volts, about 11 volts, about 12 volts, or any voltage between any of the listed values, or any appropriate voltage that may provide the maximum temperature decrease at the cooling surface. Similarly, while not limited to the following, some examples of the applied current injection may be about 75 mA, about 80 mA, about 85 mA, about 90 mA, about 95 mA, about 100 mA, about 105 mA, about 110 mA, about 115 mA, about 120 mA, about 125 mA, or any current between any of the listed values, or any appropriate current that may provide the maximum temperature decrease at the cooling surface. In an embodiment, for example, the applied DC voltage may be about 10.2 volts, and the applied current may be about 100 mA.

The thermoelectric composite may be in the form of a thermoelectric film having a thickness of about 5 mm to about 50 mm. Such a film may be produced by making an aqueous polymer solution of at least one polymer and nanoparticles of at least one paramagnetic material, and curing the solution to form a polymer composite material. The solution may be poured into a mold for curing, and the final shape, size and thickness of the material may be determined by the configuration of the mold. For aqueous solutions, the curing may be done by drying.

The electrodes may be placed in the polymer composition during curing, or may be placed in the mold prior to adding of the polymer solution to the mold. In some embodiments, electrodes may be inserted into the polymer after the polymer is cured.

A polymer composite may be produced by first forming a polymer solution of polyvinyl alcohol, sodium alginate and gelatin, followed by dispersion of the metal complex in the polymer solution. The solution may be poured into a mold and allowed to cure.

In an embodiment, a first polymer solution may be made that contains about 1.5 wt % to about 2.5 wt % polyvinyl alcohol, about 0.35 wt % to about 0.45 wt % gelatin, and about 0.35 wt % to about 0.45 wt % sodium alginate. Nanoparticles may be introduced into the polymer solution to provide about 0.5 wt % to about 1.5 wt % paramagnetic nanoparticles in the solution. Electrodes may be placed in a spaced apart configuration in a mold, the polymer/paramagnetic material solution may be poured into the mold, and allowed to cure to form a thermoelectric polymer composite material. For producing the polymer/nanoparticle solution, stock aqueous solutions of each of the components, polyvinyl alcohol, gelatin, sodium alginate, and paramagnetic material may be configured, and appropriate volumes of the stock solutions may then be intermixed, with stirring, to provide the polymer/paramagnetic material solution.

As represented in FIG. 2, a thermoelectric composite 10 as discussed above, and as may be represented by the embodiment of FIG. 1, may be used for heating or cooling an object 40 and/or the space adjacent the object, such as, for example, an internal cavity within the material. The composite 10 may have a first side 10a that heats upon application of an electric field, and a second side 10b that cools upon application of the electric field, and the composite may be placed with the corresponding first or second side adjacent the material for respectively heating or cooling the material. An electric field may be produced within the composite 10, such as via electrodes 12 and 14, and DC power supply 16 to cause a transfer of heat from the second side 10b to the first side 10a to cool the second side and heat the first side, and respectively cool or heat the material.

In an embodiment as depicted in FIG. 2, it may be desired to cool the material 40. Thermoelectric composite 10 may be placed on the material 40 with the cooling side 10b contacting the material. A heat sink 50, as represented by dashed lines, may be disposed on the opposite heating side 10a of the material 10. Upon application of a current to the composite 10, heat may be drawn from the material 40, through the composite and into the heat sink 50 that may then dissipate the heat into the ambient air.

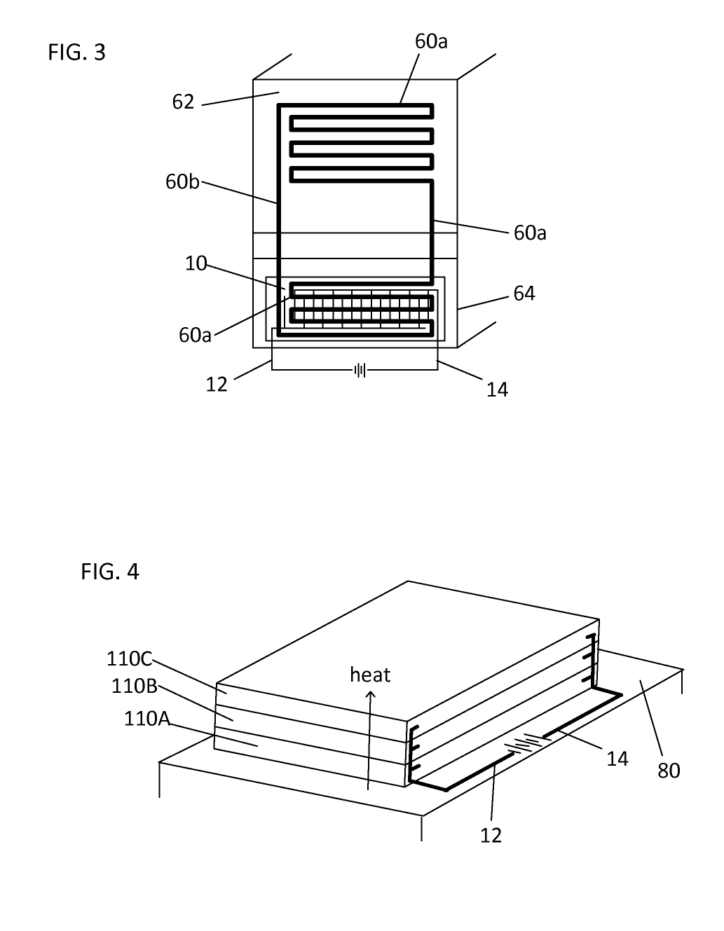

For refrigeration, such as represented in FIG. 3, a tubing system 60a-60d may be provided to carry a coolant liquid between a refrigeration chamber 62 and a fluid cooling and heat dissipation unit 64. The cooling and dissipation unit 64 may include a thermoelectric composite 10 that is configured to transfer heat from tubing portion 60a to a heat dissipation device such as a heat sink as discussed above. A fan may be provided to increase air flow across the heat sink to remove heat from the heat sink. Coolant fluid in the tubing may thereby be cooled as the coolant flows through the tubing portion 60a. Cooled coolant fluid may be directed via supply tubing 60b into the refrigeration chamber 62, where the coolant may flow through tubing portion 60c to remove heat from the chamber, thereby cooling the chamber. The heated fluid may then flow via return tubing 60d back to the cooling and dissipation unit 64 to continually repeat the cycle as needed.

In additional embodiments, the composite 10 may be molded to provide thermoelectric devices of varying shapes and sizes depending on the need, the available space, and the space of the available space. For example, a cylindrical shaped-composite may be formed to dissipate heat outwardly and remove heat from a pipe passing through the center thereof. Further, since the composite material is flexible and may be molded to a variety of shapes including appropriately placed electrodes, the whole surface of a cooling chamber may be fabricated from the composite materials.

As depicted in FIG. 4, a thermoelectric arrangement may have two or more layers of composite 10, and indicated as layers 110A, 110B, and 110C. The layers 110A, 110B, and 110C may work in conjunction with one another to improve transfer of heat from one side of the arrangement to the other. With the first layer 110A, removing heat from the material 80, the second layer 110B removing heat from the first layer, and the third layer 110C removing heat from the second layer, so that all three layers work together to remove heat from the object 80 to be cooled.

### EXAMPLES

### Example 1

### Preparation of Thermoelectric Composite Films

Various composite films of different wt % ratios were fabricated to study the effect of the following components, polyvinyl alcohol (PVA), gelatin, and sodium alginate as the polymer components, and FeCl₃ as the paramagnetic material. The following stock solutions were prepared:
A. About 5 wt % polyvinyl alcohol (purchased from Nice chemicals pvt. Ltd Product code P15629) in warm deionized water (about 45° C. to about 50° C.);
B. About 2 wt % gelatin (purchased from Thomas Baker (chemicals) ltd. product code 11/745/1887) in warm deionized water (about 45° C. to about 50° C.);
C. About 2 wt % sodium alginate (purchased from Alfa Aesar, product code J61887) in warm deionized water (about 45° C. to about 50° C.); and
D. About 5 wt % ferric chloride nanoparticles in deionized water; (FeCl₃.6H₂O has 5 unpaired d5 electrons).
   For the ferric chloride solution, FeCl₃ nanoparticles were prepared by dispersing about 5 g of anhydrous ferric chloride; (purchased from Nice Chemicals Pvt. Ltd Product code F10329) in about 50 ml of ethanol. This solution was sonicated for about 2 hours to provide measured particles sizes within about 100 nm to about 200 nm. The particles were filtered and dried.

Using the prepared stock solutions, polymer/FeCl₃ solutions were prepared according to the ratios indicated in the table below and the following procedural steps:
1. About X ml PVA stock solution were mixed with Z ml of gelatin stock solution and stirred well to achieve homogeneity. To this was added Y ml of sodium alginate stock solution, and the solution was again stirred to obtain a homogenous solution; and
2. About N ml of ferric chloride stock solution was added to the solution of step 1, drop by drop, while stirring the mixture continuously.

TABLE 1

| Composition: | |
|---|---|
| X:Y:Z:N | Observations |
| 5:5:5:5 | electrodes cannot be embedded |
| 10:10:5:5 | no polymerization |
| 10:5:5:10 | slurry formation no sheet formation |
| 10:5:10:5 | brittle composite |
| 10:5:5:5 | Flexible, stable, composite |

A mold having a size of about 7 cm by about 12 cm was formed, and an electrode arrangement as shown in FIG. 1 was placed in the mold. The main electrode portions 12a, 14a were about 10 cm long copper wires of AWG 18, and the branch electrode portions 12-1 to 12-n, 14-1 to 14-n were about 3 cm long copper wires of AWG 18, arranged with a gap of about 0.5 cm between the negative and positive electrodes. The solution of step 2 was poured into the mold and the film was dried at a constant temperature of about 50° C. to produce a film of dimensions of about 7 cm by about 12 cm by about 0.5 cm thick. If smaller gauge wire is used, thinner films may also be produced.

### Example 2

### A Thermoelectric Film and Film Characterization

As indicated in Table 1, the film formed from the 10:5:5:5 composition had better working characteristics than the other formulations and was therefore chosen for further characterization. With the corresponding indicated volumes (10 ml+5 ml+5 ml+5 ml=25 ml), the aqueous polymer/FeCl₃ solution used for the film contained the following: 10 ml of 5 wt % PVA=0.5 g PVA in final volume of 25 ml=2 wt % PVA; 5 ml 2 wt % gelatin=0.1 g gelatin in final volume of 25 ml=0.4 wt % gelatin; 5 ml 2 wt % sodium alginate=0.1 g sodium alginate in final volume of 25 ml=0.4 wt % sodium alginate; and 5 ml 5 wt % FeCl₃=0.25 g FeCl₃ in final volume of 25 ml=1 wt % FeCl₃. The wt % ratios of PVA, gelatin, sodium alginate, and FeCl₃ in the film are approximately 5:1:1:2.5.

Various assemblies and experiments with the 10:5:5:5 film were tested and a comparison was also made with a blank polymer (containing no FeCl₃). Measurements of surface temperature of the composites were tested with and without ferric chloride, with and without magnetic field, with single and multiple layers, and with variation in electric field strength and injection current.

Tables 2A and 2B depict results from a single layer composite with two electrodes spaced about 3 cm apart to determine the effect of FeCl₃ on the surface temperature of the single layer film, and show the influence of FeCl₃ nanoparticles in phonon transport.

TABLE 2A
Resistance ~1 MΩ
Without Magnetic field
PVA:Gelatin:SA:FeCl₃ = 10:5:5:5
Single layer; 2 electrodes each 3 cm apart

| Volts V | I (mA) | T (° C.) | Time (s) |
|---|---|---|---|
| 0 | 0 | 32 | 0 |
| 0.5 | 0.01 | 31 | 20 |
| 1 | 0.01 | 30 | 40 |
| 2 | 0.01 | 29 | 60 |
| 3 | 0.02 | 28 | 80 |
| 4 | 0.02 | 27 | 100 |
| 5 | 0.02 | 26 | 120 |
| 6 | 0.02 | 25 | 140 |
| 7 | 0.03 | 24 | 160 |
| 8 | 0.03 | 23 | 180 |
| 9 | 0.04 | 22 | 200 |
| 10 | 0.04 | 22 | 220 |
| 10 | 0.04 | 21 | 260 |
| 10 | 0.04 | 20 | 300 |
| 10 | 0.04 | 20 | 400 |

TABLE 2B
Resistance ~1 MΩ
Without Magnetic field
PVA:Gelatin:SA:FeCl₃ = 10:5:5:0
Single layer; 2 electrodes each 3 cm apart

| Volts V | I (mA) | T (° C.) | Time (s) |
|---|---|---|---|
| 0 | 0 | 32 | 0 |
| 0.5 | 0 | 31 | 20 |
| 1 | 0 | 30 | 40 |
| 2 | 0 | 29 | 60 |
| 3 | 0.01 | 28 | 80 |
| 4 | 0.01 | 27 | 100 |
| 5 | 0.01 | 26 | 120 |
| 6 | 0.01 | 26 | 140 |
| 7 | 0.01 | 26 | 160 |
| 8 | 0.01 | 26 | 180 |
| 9 | 0.01 | 26 | 200 |
| 10 | 0.01 | 26 | 220 |
| 10 | 0.01 | 26 | 260 |
| 10 | 0.01 | 26 | 300 |
| 10 | 0.01 | 26 | 400 |

As shown in Table 2A, the polymer with the FeCl₃ had a 12° C. temperature drop from a starting temperature of 32° C. to a final temperature of 20° C. after 400 seconds. The same composition polymer without the FeCl₃ showed only a 6° C. drop from a starting temperature of 32° C. to a final temperature of 26° C. after 400 seconds.

Tables 3A and 3B show the effect of a magnetic field on the surface temperature of the film with closer spacing of the electrodes (compared to Tables 2A, 2B).

TABLE 3A
Resistance ~1 MΩ
Without Magnetic field
PVA:Gelatin:SA:FeCl₃ = 10:5:5:5
Single layer; 2 electrode each 1.5 cm apart

| Volts V | I (mA) | T (° C.) | Time (s) |
|---|---|---|---|
| 0 | 0 | 32 | 0 |
| 0.5 | 0.01 | 31 | 20 |
| 1 | 0.03 | 30 | 40 |
| 2 | 0.03 | 28 | 60 |
| 3 | 0.04 | 26 | 80 |
| 4 | 0.05 | 24 | 100 |
| 5 | 0.05 | 23 | 120 |
| 6 | 0.06 | 20 | 140 |
| 7 | 0.07 | 16 | 160 |
| 8 | 0.08 | 10 | 180 |
| 9 | 0.09 | 7 | 200 |
| 10 | 0.1 | 6 | 220 |
| 11 | 0.15 | 5 | 240 |
| 12 | 0.25 | 4 | 260 |
| 13 | 0.3 | 3 | 280 |

TABLE 3B
Resistance ~1 MΩ
With Magnetic field
PVA:Gelatin:SA:FeCl₃ = 10:5:5:5
Single layer; 2 electrode each 1.5 cm apart

| Volts V | I (mA) | T (° C.) | Time (s) |
|---|---|---|---|
| 0 | 0.0 | 32 | 0 |
| 0.5 | 0.005 | 31 | 20 |
| 1 | 0.005 | 30 | 40 |
| 2 | 0.005 | 29 | 60 |
| 3 | 0.01 | 28 | 80 |
| 4 | 0.01 | 27 | 100 |
| 5 | 0.01 | 26 | 120 |
| 6 | 0.01 | 26 | 140 |
| 7 | 0.01 | 26 | 160 |
| 8 | 0.01 | 26 | 180 |
| 9 | 0.01 | 26 | 200 |
| 10 | 0.01 | 26 | 220 |
| 10 | 0.01 | 26 | 260 |
| 10 | 0.01 | 26 | 300 |
| 10 | 0.01 | 26 | 400 |

The results in tables 3A and 3B provide an indication of the influence of spin in addition to charge transport. In table 3A, in the presence of only an electric field, the spins of the FeCl₃ electrons are expected to be highly oriented and work in unison to remove heat from the system. The results show a decrease in the surface temperature by 29° C., from a starting temperature of 32° C. to a temperature of 3° C. after 280 seconds. In table 3B, the heat removal should mainly be due to charge transport phenomenon, because the spins should be disabled by the external magnetic field (3000 Gauss or 0.03 T). The results show a decrease in the surface temperature by only 6° C. from a starting temperature of 32° C. to a temperature of 26° C. after 400 seconds.

Tables 4A and 4B show the effect of magnetic field on the surface temperature of multi-layered film with closer spacing of the electrodes (compared to Tables 2A, 2B, 3A, 3B).

TABLE 4A
Resistance ~1 MΩ
Without Magnetic field
PVA:Gelatin:SA:FeCl₃ = 10:5:5:5
Three layer; 4 electrode each 1 cm distance

| Volts V | I (mA) | T (° C.) | Time (s) |
|---|---|---|---|
| 0 | 0 | 32 | 0 |
| 0.5 | 0.01 | 31 | 20 |
| 1 | 0.03 | 28 | 40 |
| 2 | 0.03 | 25 | 60 |
| 3 | 0.04 | 21 | 80 |
| 4 | 0.05 | 18 | 100 |
| 5 | 0.05 | 15 | 120 |
| 6 | 0.06 | 12 | 140 |
| 7 | 0.07 | 9 | 160 |
| 8 | 0.08 | 7 | 180 |
| 9 | 0.09 | 5 | 200 |
| 10 | 0.1 | 2 | 220 |
| 10.2 | 0.11 | 0 | 260 |
| 10.4 | 0.12 | −2 | 300 |
| 10.2 | 0.11 | −4 | 400 |
| 10 | 0.12 | −6 | 420 |
| 10.2 | 0.11 | −6 | 440 |

TABLE 4B
Resistance ~1 MΩ
With Magnetic field
PVA:Gelatin:SA:FeCl₃ = 10:5:5:5
Three layer; 4 electrode each 1 cm distance

| Volts V | I (mA) | T (° C.) | Time (s) |
|---|---|---|---|
| 0 | 0 | 32 | 0 |
| 0.5 | 0.01 | 31 | 20 |
| 1 | 0.03 | 30 | 40 |
| 2 | 0.03 | 30 | 60 |
| 3 | 0.04 | 29 | 80 |
| 4 | 0.05 | 29 | 100 |
| 5 | 0.05 | 29 | 120 |
| 6 | 0.06 | 28 | 140 |
| 7 | 0.07 | 28 | 160 |
| 8 | 0.08 | 28 | 180 |
| 9 | 0.09 | 27 | 200 |
| 10 | 0.1 | 27 | 220 |
| 10.2 | 0.11 | 25 | 260 |
| 10.4 | 0.12 | 25 | 300 |
| 10.2 | 0.11 | 24 | 400 |
| 10 | 0.12 | 24 | 420 |
| 10.2 | 0.11 | 24 | 440 |

The results in Tables 4A and 4B provide an indication of the effect of magnetic field on the surface temperature of a multi-layered film with closer spacing of the electrodes, and show the influence of spin in addition to charge transport. In Table 4A, in the presence of only an electric field, the spins of the FeCl₃ should be highly oriented and work in unison to remove heat from the system, and lower the surface temperature by 38° C. The results show a decrease in the surface temperature by 38° C., from a starting temperature of 32° C. to a temperature of −6° C. after 440 seconds. In Table 4B, the heat removal should mainly be due to charge transport phenomenon, because the spin induced phonon transports should be disabled by the external magnetic field (3000 Gauss or 0.03 T). The results show a decrease in the surface temperature by 8° C., from a starting temperature of 32° C. to a temperature of 24° C. after 440 seconds.

The efficiency of a thermoelectric device may be measured by calculating a corresponding thermoelectric figure of merit (ZT) and coefficient of performance (COP). The ZT value may be calculated from the following formula: ZT=σS²T/κ, where S is the Seebeck coefficient, σ is electrical conductivity of the material, κ=thermal conductivity of the material and T is the absolute temperature (T1+T2)/2. The ZT values for the 10:5:5:5 film and measurements for determining the values are presented in Table 5.

TABLE 5

| Volts | | I | T | | | | | | |
|---|---|---|---|---|---|---|---|---|---|
| V | ΔV | (mA) | deg K | (T1 + T2)/2 | σ | k | S = ΔV/ΔT | Z = σS²/K | ZT |
| 0.5 | 0.5 | 0.01 | 304 | 304 | 0.685 | 0.04 | 0.001645 | 4.63E−05 | 0.014083 |
| 1 | 0.75 | 0.03 | 301 | 302.5 | 0.685 | 0.04 | 0.002479 | 0.000105 | 0.031844 |
| 2 | 1.5 | 0.03 | 298 | 299.5 | 0.685 | 0.04 | 0.005008 | 0.00043 | 0.128652 |
| 3 | 2.5 | 0.04 | 294 | 296 | 0.685 | 0.04 | 0.008446 | 0.001222 | 0.361592 |
| 4 | 3.5 | 0.05 | 291 | 292.5 | 0.685 | 0.04 | 0.011966 | 0.002452 | 0.717201 |
| 5 | 4.5 | 0.05 | 288 | 289.5 | 0.685 | 0.04 | 0.015544 | 0.004138 | 1.197863 |
| 6 | 5.5 | 0.06 | 285 | 286.5 | 0.685 | 0.04 | 0.019197 | 0.006311 | 1.808137 |
| 7 | 6.5 | 0.07 | 282 | 283.5 | 0.685 | 0.04 | 0.022928 | 0.009002 | 2.552138 |
| 8 | 7.5 | 0.08 | 280 | 281 | 0.685 | 0.04 | 0.02669 | 0.012199 | 3.428047 |
| 9 | 8.5 | 0.09 | 278 | 279 | 0.685 | 0.04 | 0.030466 | 0.015895 | 4.4347 |
| 10 | 9.5 | 0.1 | 275 | 276.5 | 0.685 | 0.04 | 0.034358 | 0.020216 | 5.589625 |
| 10.2 | 10.1 | 0.11 | 273 | 274 | 0.685 | 0.04 | 0.036861 | 0.023269 | 6.375625 |
| 10.4 | 10.3 | 0.12 | 271 | 272 | 0.685 | 0.04 | 0.037868 | 0.024557 | 6.67938 |
| 10.2 | 10.3 | 0.11 | 269 | 270 | 0.685 | 0.04 | 0.038148 | 0.024922 | 6.728856 |
| 10 | 10.1 | 0.12 | 267 | 268 | 0.685 | 0.04 | 0.037687 | 0.024322 | 6.518363 |

The average ZT value is approximately 3.1. COP value may be determined from the formula: COP_{cooling}=T_{cold}/(Tₕₒₜ−T_{cold}). From the measurements, COP is estimated to be around 7.2. Composites created as presented above have an improved ZT and use significantly less current (by up to about ten times less) as compared to other devices. For example, Bi₂Te/Sb₂Te₃ and PbSeTe/PbTe superlattice thin films have COP values of about 2.

The results in Table 5 provide an indication that, at higher electric fields (high voltage), the cooling effect should be significant because of high ZT, without a correspondingly large increase in current. This provides an indication that the spins of electrons are playing a major role in heat pumping to introduce a large thermal gradient, while the effect is insignificant at low fields because of less influence in alignment of spins.

### Example 3

### Use of a Thermoelectric Composition for Cooling

A thermoelectric material will be produced having three layers of the composite produced as in Example 1 and produced from the 10:5:5:5 solution. The material sheet will be molded in a substantially U-shape to fit around the upper surface and sides of a cubic refrigeration chamber. The refrigeration chamber will have a thin metallic surface for protection of the thermoelectric sheet and improved heat transfer to the sheet, and the inner surface of the sheet will be adhered to the metallic surface. The outer surface of the thermoelectric sheet will also be adhered to a metallic sheet to draw heat from the thermoelectric layer. An airflow chamber will be constructed around the thermoelectric layer, and a fan will be used to pass cooling air through the airflow chamber and around the outer surface to remove heat from the surface.

An electric current will be applied to the thermoelectric layer and fan to begin transfer of heat from the refrigeration chamber to the exterior surface, from which the heat will be removed by the flowing air. The unit will be thermostatically controlled to provide cooling on demand.

Most materials with un-paired electron spins will exhibit paramagnetic properties. The un-paired electrons spin align with the applied E/M field and the spin alignment disappears when the E/M field is removed. Under normal conditions, most electrons would occupy low-energy states and just a few would populate higher-energy states. In population-inverted states, this situation can be reversed as more electrons populate higher, rather than lower, energy states. In materials having 5 d-orbital un-paired electrons, such as in FeCl₃, inverted population can be easily achieved by exposing the material to an electric/magnetic field.

Molecules of paramagnetic materials have permanent magnetic moments (dipoles), even in the absence of an applied field. The permanent moment generally is due to the spin of unpaired electrons in molecular electron orbitals. In paramagnetic material, the dipoles do not interact with one another and are randomly oriented in the absence of an external field due to thermal agitation, resulting in zero net magnetic moment. When an electric/magnetic field is applied, the dipoles will tend to align with the applied field, resulting in a net magnetic moment in the direction of the applied field. This alignment can be understood to occur due to a torque being provided on the magnetic moments by an applied field that tries to align the dipoles parallel to the applied field. If there is sufficient energy exchange between neighboring dipoles he dipoles should interact, and may spontaneously align or anti-align and form small magnetic domains. In thermodynamic terms, the paramagnetic properties of un-paired electrons represent separate degrees of freedom (dimensions in phase space) in addition to the normal degrees of freedom (vibration and movement) possessed by all materials.

In accordance with thermodynamic principles, unlike atomic or molecular vibration/movement which exhibit strong coupling between dimensions in phase space (degrees of freedom), electron spin alignment should (in most cases) only weakly be coupled to other dimensions of phase space. For this reason, it can be appropriate to consider paramagnetic materials as having two separate populations (electron spins, and bulk vibration/movement). Therefore, in many situations, each population should possess separate numerical values for entropy, energy, and temperature.

In the presence of an electric/magnetic field, the rules of quantum electrodynamics require the un-paired electron spins be either aligned, or anti-aligned to the field vector (two dimensions in phase space). Therefore, un-paired electron spins in FeCl₃, for example, represent an excellent material for constructing an inverted population. The following discussion takes into consideration a population of un-paired electron spins at the instant just before, and just after the composite material (having paramagnetic nanoparticles as presented above) is exposed to an electric field.

Before injection of the electric field, there should be no un-paired electron spin alignment, and therefore the un-paired electron spins have nearly limitless dimensions in phase space (degrees of freedom), and the un-paired electron spin population should be in thermal equilibrium with the bulk population.

Upon application of an electric field, the external field should shift the un-paired electron spin population of the paramagnetic material core into an inverted population state. On exposure to an electric field, phase space may collapse to just two-dimensions because the un-paired electron spins must either be aligned or anti-aligned to the applied E/M magnetic field. Then, since the paramagnetic polarization at this instant is zero, 50% should be spin aligned, and 50% should be anti-spin aligned. During this step, as un-paired electron spins should align with the applied E-M field, the entropy of the population should decline, and heat should flow out of the un-paired electron spin population, and into the bulk material population. Therefore, the temperature of the un-paired electron spin population should no longer be in thermal equilibrium with the bulk population.

Next, as current flow rises, the intensity of the E-M field should also increase, thereby increasing paramagnetic polarization. Anti-aligned electron spins should then be flipping into alignment with the E-M field, and the change in temperature of the electron spin population should now be negative, that is, getting lower than the ambient temperature and declining.

Adiabatic demagnetization may then cause a rapid decline in the temperature of the un-paired electron spin population. During this decline in temperature, the un-paired electron spin population should momentarily dip below the Curie transition temperature thereby causing a momentary rise in total magnetic flux as paramagnetic spin coupling forces contribute to overall un-paired electron spin alignment. This may force the temperature of the un-paired electron spin population to fall below the Curie transition temperature, and thereby cause the magnetic susceptibility to become high (onset of ferromagnetic behavior).

Following this, a thermal equalization should occur, wherein the electron spin population and the bulk material population once more, achieve thermal equilibrium with the ambient environment, albeit at a temperature lower than it was previously, and this should allow sufficient time for the heat deficiency (in the flipping stage described above), to be replenished from the ambient environment. Thus, a continuous pumping of heat may occur by utilizing the spins of unpaired electron as the working fluid.

Therefore, on the basis of thermodynamic working fluid theory: un-paired electron spins in paramagnetic materials may exhibit the characteristics of an inverted population when exposed to an external E-M field; a population of un-paired electron spins may be made to interact with the ambient surroundings/space, thereby transporting thermal energy, and making the thermal energy available for work; and a cyclic heat engine based on a working fluid, utilizing an inverted population of un-paired electron spins should be possible.

Alternatively, in accordance with the Spin-Peltier effect, the flow of electric charge in a given material is determined by the electrical conductance of the material and the applied electric field. Similarly, the flow of heat is determined by the heat conductance and the temperature gradient, and interactions between charge and heat transport give rise to Peltier effects. However, electrons also have spin, which leads to spin-dependent thermoelectric effects when there is an imbalance of unpolarized spins, that is, spin accumulation. Electrons of one spin direction and electrons of the other spin direction carry the same amount of heat, so the size of the conventional Peltier effect depends on the amount of heat carried per unit of electric charge, irrespective of spin.

The situation in a paramagnet is different because the two spin channels carry different amounts of heat per electron, as an example, electrons of one spin orientation may carry three times as much heat as the other electrons. A spin current then does carry heat, even though there is no net flow of electron charge. Moreover, this heat flow depends on the magnitude of the spin current, and this is the spin-dependent Peltier effect.

A spin-dependent Peltier effect hinges on the fact that the electrons carrying the charge current are spin-½ particles, which means that they can be in one of two spin states. These states, which have opposite angular momentum, are usually referred to as spin-up and spin-down. If the magnitudes and/or directions of the spin-up and spin-down electrons can be made different, then a spin-polarized heat current, that is, a heat flow gradient with effectively more spin-up electrons than spin-down electrons, or vice versa, will be established, and this should be the case with a paramagnetic material, such as FeCl₃. This spin dependence of heat transport implies that thermoelectric phenomena in paramagnetic nanoparticles structures are also spin dependent.

Thus, depending on the experimental configuration and choice of paramagnetic materials, the spin-dependent charge currents can carry different amounts of heat, such that the lower layer can become hotter or cooler. The results as presented above, indicate that by introducing an additional perpendicular magnetic field, the difference in the amount of heat carried by un-polarized spin electrons greatly influences the temperature gradient across the paramagnetic material. One potential advantage of spin-related thermoelectric behavior in paramagnetic material is the easy control of the thermal behavior.

Therefore, on the basis of spin-Peltier theory, one promising approach for increasing the efficiency and versatility of thermoelectric devices involves exploiting the spin of the electron, in addition to its charge and heat transport properties. In the concept of spin caloritronic material as provided herein the transport of heat is intertwined with the transport of spin (that is, the intrinsic angular momentum of electrons), thus opening up the control of heat and spin currents. In effect, the proposed material is an extension and combination of conventional thermoelectrics (which does not consider spin transport) and conventional spintronics (which does not consider heat transport).

This disclosure is not limited to the particular systems, devices and methods described, as these may vary. The terminology used in the description is for the purpose of describing the particular versions or embodiments only, and is not intended to limit the scope.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

What is claimed is:

1. A cooling device comprising:
a polymer composite comprising:
at least one polymer; and
nanoparticles that include at least one paramagnetic material.

2. The cooling device of claim 1, wherein the paramagnetic material has at least one of:
four unpaired electrons; and
an effective magnetic moment of at least about 5.

3. The cooling device of claim 1, wherein:
the polymer composite comprises the at least one polymer and the nanoparticles in a weight ratio of about 2:1 to about 4:1.

4. The cooling device of claim 1, wherein:
the at least one polymer comprises at least one of gelatin, polyvinyl alcohol, alginate, polypyrrole, polymethyl methacrylate, and polyurethane.

5. The cooling device of claim 1, wherein the at least one paramagnetic material comprises at least one metal complex of a transition metal selected from FeCl₃.6H₂O, NH₄[Fe(SO₄)₂].12H₂O, (NH₄)₂[Mn(SO₄)₂].6H₂O, [Mn(NH₃)₆]Cl₂, NiCl₂.6H₂O, CoCl₂.6H₂O, or a combination thereof.

6. The cooling device of claim 1, wherein:
the at least one polymer comprises polyvinyl alcohol, gelatin, and an alginate, in corresponding weight ratios of about 3.5-6.2:0.8-1.2:0.8-1.2.

7. The cooling device of claim 1, wherein:
the at least one polymer comprises at least one of gelatin, polyvinyl alcohol, alginate, polypyrrole, polymethyl methacrylate, and polyurethane;
the at least one paramagnetic material comprises at least one metal complex of a transition metal; and
the polymer composite comprises the at least one polymer and the nanoparticles in a weight ratio of about 2:1 to about 4:1.

8. The cooling device of claim 1, further comprising at least two spaced-apart electrodes embedded in the polymer composite and spaced from one another at a distance such that the at least two spaced-apart electrodes are operable to facilitate a cooling effect of the device.

9. The cooling device of claim 8, wherein the at least two electrodes comprise a plurality of oppositely chargeable electrodes alternately interspersed in the polymer composite and spaced at most about 0.5 cm apart.

10. The cooling device of claim 8, wherein the at last two electrodes comprise a first comb-shaped electrode and a second comb-shaped electrode, wherein each of the first and second comb-shaped electrodes have a main branch portion with a multiplicity of substantially parallel projecting arm portions extending therefrom, and wherein the projecting arm portions of the first comb-shaped electrodes are interleaved between the projecting arm portions of the second comb-shaped electrode.

11. The cooling device of claim 8, wherein:
the at least two electrodes are configured operable to generate an electric field within the composite; and
the composite is configured in conjunction with the electric field to have at least one of:
a thermoelectric figure of merit (ZT) of at least about 3 upon generation of the electric field; and
a coefficient of performance of at least about 7 upon generation of the electric field.

12. The cooling device of claim 1, further comprising:
at least two spaced-apart electrodes embedded in the polymer composite and spaced from one another at a distance; and
a power source coupled to the at least two spaced-apart electrodes and operable to apply a potential difference across the electrodes such that the at least two spaced-apart electrodes are operable to facilitate a cooling effect of the device.

13. The cooling device of claim 12, wherein:
the composite is a film;
the at least one paramagnetic material comprises at least one metal complex of a transition metal; and
the polymer comprises at least one of gelatin, polyvinyl alcohol, and sodium alginate.

14. The cooling device of claim 1, wherein:
the at least one paramagnetic material comprises at least one metal complex of a transition metal, wherein the nanoparticles have a cross-sectional dimension of less than about 200 nm; and
the at least one polymer includes polyvinyl alcohol, gelatin and an alginate of at least one of sodium alginate and potassium alginate.

15. The cooling device of claim 14, wherein the polymer composite comprises the polyvinyl alcohol, the gelatin, the alginate, and the nanoparticles in corresponding weight ratios of about 4.5-5.5:0.9-1.1:0.9-1.1:2.2-2.5.

16. A method for producing a cooling device, the method comprising forming a polymer composite by dispersing nanoparticles of at least one paramagnetic material in a polymer.

17. The method of claim 16, wherein forming the polymer composite comprises dispersing nanoparticles of at least one paramagnetic material having at least one of:
four unpaired electrons; and
an effective magnetic moment of at least about 5.

18. The method of claim 16, wherein:
forming the polymer composite further comprises forming a first polymer solution of at least one of: at least one polymer and polymer precursors;
the dispersing comprises dispersing nanoparticles of a metal complex of a transition metal in the first polymer solution to produce a second polymer solution; and
the method further comprises:
pouring the second polymer solution into a mold; and
curing the second polymer solution to form the polymer composite.

19. The method of claim 16, further comprising contacting the polymer composite with at least two spaced-apart electrodes that are configured operable to be oppositely charged by a power source to produce an electric field within the polymer composite.

20. The method of claim 16, wherein:
forming the polymer composite further comprises forming a first polymer solution of polyvinyl alcohol, sodium alginate and gelatin;
the dispersing comprises dispersing nanoparticles of a metal complex of a transition metal in the first polymer solution to produce a second polymer solution; and
the method further comprises:
placing at least two electrodes in a mold at a distance from one another, wherein the at least two electrodes are operable to facilitate a cooling effect of the cooling device;
pouring the second polymer solution into the mold; and
curing the second polymer solution around the electrodes to form the polymer composite.

21. The method of claim 20, wherein placing the at least two electrodes comprises:
placing oppositely chargeable first and second comb-shaped electrodes in the mold, wherein both of the first and second comb-shaped electrodes have a main branch portion with a multiplicity of substantially parallel projecting arm portions extending therefrom at intervals of at most about 1 cm between projecting arm portions; and
interleaving the projecting arm portions of one of the electrodes between the projecting arm portions of the other of the electrodes to provide a spacing of at most about 0.5 cm between the interleaved arms.

22. The method of claim 21, wherein the dispersing comprises:
providing nanoparticles having a cross-sectional size of less than or equal to about 200 nm and dispersing the 200 nm nanoparticles in the first polymer solution.

23. The method of claim 22, wherein the providing comprises:
introducing nanoparticles of a metal complex selected from FeCl₃.6H₂O, NH₄[Fe(SO₄)₂].12H₂O, (NH₄)₂[Mn(SO₄)₂].6H₂O, [Mn(NH₃)₆]Cl₂, NiCl₂.6H₂O, CoCl₂.6H₂O, or a combination thereof, in an alcohol solution; and
sonicating the alcohol solution for a period of time sufficient to reduce a cross-sectional size of the nanoparticles to less than about 200 nm.

24. The method of claim 16, wherein:
the forming the polymer composite further comprises forming a first polymer solution of about 1.5 wt % to about 2.5 wt % polyvinyl alcohol, about 0.35 wt % to about 0.45 wt % gelatin, and about 0.35 wt % to about 0.45 wt % alginate; and
the dispersing comprises dispersing an amount of the nanoparticles into the first polymer solution to provide a second polymer solution of about 0.5 wt % to about 1.5 wt % nanoparticles in the solution.

25. The method of claim 24, further comprising:
placing at least two oppositely chargeable electrodes a distance of at most about 0.5 cm from one another;
pouring the polymer solution over the electrodes; and
curing the polymer solution to form the polymer composite.

26. The method of claim 16, wherein forming the polymer composite comprises:
forming a first aqueous solution of polyvinyl alcohol;
forming a second aqueous solution of gelatin;
forming a third aqueous solution of sodium alginate;
forming a fourth aqueous solution of nanoparticles of at least one of the metal complexes FeCl₃.6H₂O, NH₄[Fe(SO₄)₂].12H₂O, (NH₄)₂[Mn(SO₄)₂].6H₂O, [Mn(NH₃)₆]Cl₂, NiCl₂.6H₂O, and CoCl₂.6H₂O;
contacting the first aqueous solution with the second aqueous solution to produce a first mixed solution;
introducing the third aqueous solution into the first mixed solution to produce a polymer solution;
adding the fourth aqueous solution into the polymer solution at a rate sufficient for dispersion of the nanoparticles into the polymer solution to produce a fifth polymer solution; and
curing the fifth polymer solution to form the polymer composite wherein the polymer composite comprises the polyvinyl alcohol, the gelatin, the sodium alginate, and the nanoparticles in corresponding weight ratios of about 4.5-5.5:0.9-1.1:0.9-1.1:2.2-2.5.

27. The method of claim 26, wherein:
the method further comprises:
placing at least two oppositely chargeable electrodes into a mold having a cavity for forming a film;
spacing the at least two oppositely chargeable electrodes within the cavity at a distance of at most about 0.5 cm between the oppositely chargeable electrodes; and
pouring the fifth polymer solution into the cavity of the mold and around the electrodes; and
the curing comprises curing the fifth polymer solution in the mold to form a film of the polymer composite.

28. A thermal transfer system configured to heat or cool a material, the thermal transfer system comprising:
a thermal transfer device comprising:
a polymer composite comprising a polymer and nanoparticles of at least one paramagnetic material;
a pair of electrodes coupled to the polymer composite, wherein the pair of electrodes are configured to produce an electric field within the polymer composite when active;
a first side of the thermal transfer device that heats responsive to the electric field;
a second side of the thermal transfer device that cools responsive to the electric field; and
wherein the material is thermally coupled to either the first side or the second side of the thermal transfer device.

29. The thermal transfer system of claim 28, wherein:
the thermal transfer system further comprises a power source with a positive terminal and a negative terminal, wherein the negative terminal of the power source is coupled to a first electrode of the pair of electrodes, and wherein the positive terminal of the power source is coupled to a second electrode of the pair of electrodes; and
the pair of electrode are spaced-apart in the polymer composite by a distance that is sufficient to produce the electric field in the polymer composite when a potential difference is applied across the pair of electrodes by the power source.

30. The thermal transfer system of claim 28, wherein the at least one paramagnetic material comprises at least one transition metal complex having at least one of: at least four unpaired electrons and an effective magnetic moment of at least about 5.

31. The thermal transfer system of claim 28, wherein:
the polymer of the polymer composite comprises a molded polymer film having a molded shape configured to match a shape of the material;
the at least one paramagnetic material comprises a transition metal complex selected from FeCl₃.6H₂O, NH₄[Fe(SO₄)₂].12H₂O, (NH₄)₂[Mn(SO₄)₂].6H₂O, [Mn(NH₃)₆]Cl₂, NiCl₂.6H₂O, CoCl₂.6H₂O, or a combination thereof; and
the polymer comprises polyvinyl alcohol, sodium alginate and gelatin.

32. The thermal transfer system of claim 31, wherein:
the second side of the thermal transfer device, which corresponds to a side of the molded polymer film, is thermally coupled to the material such that the polymer composite transfers heat away from the material responsive to the electric field effective to cool the material.

33. The thermal transfer system of claim 28, wherein:
the polymer composite of the thermal transfer device comprises polyvinyl alcohol, gelatin, an alginate, and the nanoparticles in corresponding weight ratios of about 4.5-5.5:0.9-1.1:0.9-1.1:2.2-2.5;
the alginate is at least one of sodium alginate and potassium alginate;
the at least one paramagnetic material is at least one of: FeCl₃.6H₂O, NH₄[Fe(SO₄)₂].12H₂O, (NH₄)₂[Mn(SO₄)₂].6H₂O, [Mn(NH₃)₆]Cl₂, NiCl₂.6H₂O, and CoCl₂.6H₂O; and
the pair of electrode of the thermal transfer device are oppositely chargeable electrodes disposed in the polymer composite at a distance from one another sufficient to facilitate thermal energy transfer at the corresponding side that is thermally coupled to the material.
